(19) United States
(12) Patent Application Publication
(10) Pub. No.: US 2026/0367171 A1
(43) Pub. Date: Nov. 19, 2026

(54) APPARATUS AND METHOD FOR MANAGING A BATTERY OF AN ELECTRIFIED VEHICLE

(71) Applicants: HYUNDAI MOTOR COMPANY, Seoul (KR); KIA CORPORATION, Seoul (KR)

(72) Inventors: Jung Heon Lee, Hwaseong-si (KR); Hyun Jun Jang, Hwaseong-si (KR)

(73) Assignees: HYUNDAI MOTOR COMPANY, Seoul (KR); KIA CORPORATION, Seoul (KR)

(21) Appl. No.: 19/352,215

(22) Filed: Oct. 7, 2025

(30) Foreign Application Priority Data
May 13, 2025 (KR) 10-2025-0062093

(51) Int. Cl. G01R 31/392; B60L 58/16; G01R 31/36; G01R 31/367; G01R 31/389; G01R 31/396; H01M 10/42

(52) U.S. Cl. CPC G01R 31/392; B60L 58/16; G01R 31/3648; G01R 31/367; G01R 31/389; G01R 31/396; H01M 10/425; H01M 2010/4271

(57) ABSTRACT

A battery management apparatus includes a memory storing a resistance value of each battery cell among a plurality of battery cells of a battery. The battery management apparatus also includes a processor configured to determine whether there is an abnormality in each battery cell among the plurality of battery cells and an abnormality type by relatively comparing the resistance value of each battery cell. The processor is also configured to control each battery cell, among the plurality of battery cells, according to whether there is the abnormality in the battery cell and the abnormality type.

### CROSS-REFERENCE TO RELATED APPLICATION(S)

This application claims the benefit of and priority to Korean Patent Application No. 10-2025-0062093, filed on May 13, 2025, in the Korean Intellectual Property Office, the entire contents of which are hereby incorporated herein by reference.

### TECHNICAL FIELD

The present disclosure relates to a battery management apparatus and a battery management method for diagnosing an abnormality in cells of a battery of an electrified vehicle.

### BACKGROUND

With a growing interest in the environment in recent years, use of eco-friendly vehicles with an electric motor as a power source is on the rise. Eco-friendly vehicles may be electrified vehicles. Representative examples of eco-friendly vehicles include hybrid electrified vehicles (HEVs) and electrified vehicles (EVs).

A battery used in an electrified vehicle may be configured in the form of a battery pack (or a battery system) including a plurality of battery cells. A battery pack may be configured by connecting a plurality of battery cells in series or in parallel. The performance of the battery pack may vary depending on the state of each battery cell.

When there is an imbalance in voltage or temperature between battery cells, the output performance of a battery may decrease, a specific cell in the battery may be degraded, and cell swelling may occur. Furthermore, when an abnormality occurs in one battery cell in a battery pack, heat transfer may cause an abnormality in adjacent battery cells.

The matters described in this Background section are intended to aid in the understanding of the background of the present disclosure, and should not be interpreted to mean that the matters fall within the purview of the related art already known to those having ordinary skill in the art.

### SUMMARY

Embodiments of the present disclosure provide a method and an apparatus that may maintain balance between battery cells and accurately diagnose an abnormal cell.

Embodiments of the present disclosure provide a method and an apparatus that may diagnose an abnormal cell regardless of the type of battery, for various types of batteries, including, for example, a lithium-ion battery (LIB) using a liquid electrolyte and an all-solid-state battery (ASSB) using a solid electrolyte, that may be used in an electrified vehicle.

Aspects of the present disclosure provide a battery management apparatus and a battery management method for diagnosing and appropriately controlling an abnormal cell in a battery of an electrified vehicle including a plurality of battery cells.

The technical subjects pursued in the present disclosure may not be limited to the above-mentioned technical subjects. Other technical subjects that are not mentioned herein may be more clearly understood from the following description by those having ordinary skill in the art to which the present disclosure pertains.

According to an embodiment, a battery management apparatus is provided. The battery management apparatus includes a memory storing a resistance value of each battery cell among a plurality of battery cells of a battery. The battery management apparatus also includes a processor configured to determine i) whether there is an abnormality in each battery cell among the plurality of battery cells and ii) an abnormality type based on the resistance value of the battery cell. The processor is also configured to control each battery cell, among the plurality of battery cells, according to whether there is the abnormality in the battery cells and the abnormality type.

According to an embodiment, the processor may be configured to determine whether there is the abnormality in each battery cell based on resistance value data normalized by dividing the resistance value of each battery cell by an average resistance value of all battery cells among the plurality of battery cells.

According to an embodiment, the processor may be configured to determine whether there is the abnormality in each battery cell based on standardized resistance value data obtained by standardizing the resistance value of the battery cell.

According to an embodiment, the processor may be configured to determine, as an abnormal cell, a battery cell, among the plurality of battery cells, having a normalized resistance that satisfies a preset first threshold condition.

According to an embodiment, the processor may be configured to determine whether there is the abnormality in a battery cell, among the plurality of battery cells, based on a change rate of a normalized resistance value of the battery cell over time.

According to an embodiment, the processor may be configured to determine whether there is the abnormality in a battery cell, among the plurality of battery cells, based on a change rate of a plurality of local minimums in a graph representing a normalized resistance value of the battery cell over time.

According to an embodiment, the processor may be configured to determine whether there is the abnormality by comparing slopes of linear models, each linear model representing a change in a normalized resistance value of a battery cell, among the plurality of batter cells, over time.

According to an embodiment, the processor may be configured to determine, as an abnormal cells, a battery cell, among the plurality of battery cells, having a standardized resistance value that satisfies a preset second threshold condition.

According to an embodiment, the processor may be configured to, based on determining that there is an abnormal cells, among the plurality of battery cells, deactivate the.

According to an embodiment, the processor may be configured to determine a degradation type of the abnormal cell according to the abnormality type.

According to an embodiment, the processor may be configured to determine a battery cell, among the plurality of battery cells, as an abnormal cell and deactivate the battery cell, based on a condition that a preset number or more of a same abnormality type is accumulated in any one of the battery cells.

According to an embodiment, the processor may be configured to determine the resistance value of each battery cell by performing regression analysis according to a preset condition, based on current and voltage data of the battery cell.

According to an embodiment, the processor may be configured to determine, for each battery cell among the plurality of battery cells, a linear model representing a relationship between the current and voltage data of the battery cell by using a least squares technique. The processor may also be configured to determine, for each battery cell among the plurality of battery cells, the resistance value of each battery cell, based on a slope of the linear model determined for the battery cells.

According to an embodiment, the preset condition may be a condition configured based on a charging and discharging ratio in each battery cell.

According to an embodiment, the preset condition may be a condition configured based on a distribution of the current and voltage data of each battery cell.

According to another embodiment, a battery management method is provided. The battery management method includes storing a resistance value of each battery cell among a plurality of battery cells of a battery. The battery management method also includes determining whether there is an abnormality in each battery cell, among the plurality of battery cells, based on the resistance value of each battery. The battery management method additionally includes selectively deactivating each battery cell, among the plurality of battery cells, according to whether there is the abnormality in the battery cell.

According to an embodiment, determining whether there is the abnormality in each battery cell may include determining whether there is the abnormality in each battery cell based on resistance value data normalized by dividing the resistance value of each battery cell by an average resistance value of all battery cells and standardized resistance value data obtained by standardizing the resistance value of each battery cell.

According to an embodiment, determining whether there is the abnormality in each battery cell, among the plurality of battery cells, may further include determining, as an abnormal cell, a battery cell having a normalized resistance value that satisfies a preset first threshold condition or a battery cell having a standardized resistance value that satisfies a preset second threshold condition.

According to an embodiment, determining whether there is the abnormality in a battery cell, among the plurality of battery cells, may further include determining whether there is the abnormality based on a change rate of a normalized resistance value of the battery cell over time.

According to an embodiment, determining whether there is the abnormality in each battery cell, among the plurality of battery cells, may include determining whether there is the abnormality by relatively comparing slopes of linear models, each linear model representing a change in a normalized resistance value of a battery cell, among the plurality of battery cells, over time.

A battery management apparatus and method according to embodiments may diagnose whether there is an abnormality in each cell and an abnormality type by comparing the resistance value of each cell with respect to various types of batteries. Further, when an abnormal cell is discovered, the battery management apparatus and method may deactivate the cell to safely manage a battery.

Advantageous effects obtainable from the present disclosure are not limited to the above-mentioned effects. Other effects that are not mentioned herein should be more clearly understood from the following descriptions by those having ordinary skill in the art to which the present disclosure pertains.

### BRIEF DESCRIPTION OF THE DRAWINGS

The above and other aspects, features, and advantages of the present disclosure should be more apparent from the following detailed description taken in conjunction with the accompanying drawings, in which:

FIG. 1 is a block diagram illustrating a battery management apparatus and a battery pack of an electrified vehicle, according to an embodiment;

FIG. 2 is a graph illustrating an example of a process in which a processor determines the resistance value of each cell, according to an embodiment;

FIG. 3 is a graph showing the resistance value of each cell as a function of time, stored in a memory, according to an embodiment;

FIG. 4 is a graph showing data in which the resistance value of each cell is normalized, according to an embodiment;

FIG. 5 is a graph showing data in which the resistance value of each cell is standardized, according to an embodiment;

FIG. 6 is a graph showing a normalized resistance value for one cell as a function of time and a slope thereof, according to an embodiment;

FIG. 7 is a graph showing a normalized resistance value for a specific cell as a function of time and a slope between local minimums thereof, according to an embodiment;

FIG. 8 is a graph comparing a change in the normalized resistance value of each cell in a battery pack over time, according to an embodiment; and

FIG. 9 is a flowchart illustrating an example of a process in which a processor determines whether a cell is abnormal and an abnormality type, according to an embodiment.

### DETAILED DESCRIPTION

Hereinafter, embodiments of the present disclosure are described in detail with reference to the accompanying drawings. In the following description, the same or similar elements are designated with the same or similar reference numerals regardless of figure numbers, and duplicate descriptions thereof have been omitted. The terms “module” and “unit” used for the elements in the following description are given or interchangeably used for ease of description, and do not have distinct meanings or roles by themselves. Furthermore, in describing embodiments set forth herein, where it was determined that a detailed description of known features or functions would obscure the gist of the present disclosure, the detailed description thereof has been omitted. In addition, it should be appreciated that the accompanying drawings are provided only for the sake of easy understanding of the embodiments set forth herein, and the technical idea of the present disclosure is not limited to the accompanying drawings. Rather, the present disclosure includes all modifications, equivalents, or alternatives falling within the spirit and scope of the present disclosure.

Terms including an ordinal number such as “a first” and “a second” may be used herein to describe various elements, but the elements are not limited to the terms. These terms are used merely for the purpose of distinguishing one element from other elements.

In the case where an element is referred to as being “connected” or “coupled” to any other elements, it should be understood that not only the element may be directly connected or coupled to the other elements, but also one or more other elements may exist therebetween. Contrarily, in the case where an element is referred to as being “directly connected” or “directly coupled” to any other element, it should be understood that no other element exists therebetween.

A singular expression may include a plural expression unless they are definitely different in the context.

As used herein, the expression “include,” “comprise,” or “have,” or the like, is intended to specify the existence of mentioned features, numbers, steps, operations, elements, components, or combinations thereof, and should be construed as not precluding the possible existence or addition of one or more other features, numbers, steps, operations, elements, components, or combinations thereof.

When a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, or the like may separately embody or be included with one or more processors and a memory, such as a non-transitory computer-readable media, as part of the apparatus. The one or more processors may be configured to implement computer-readable instructions stored in the memory to perform the described operations.

A unit or a control unit included in names such as a Motor Control Unit (MCU) is merely a term widely used for naming a controller configured to control a specific function of a vehicle, but does not mean a generic function unit. For example, in order to control a function that a control unit is responsible for, each control unit may include a communication device configured to communicate with a sensor or another control unit, a memory configured to store an operation system, a logic command, or input/output information, and at least one processor configured to perform determination, calculation, decision or the like which are required for responsible function controlling.

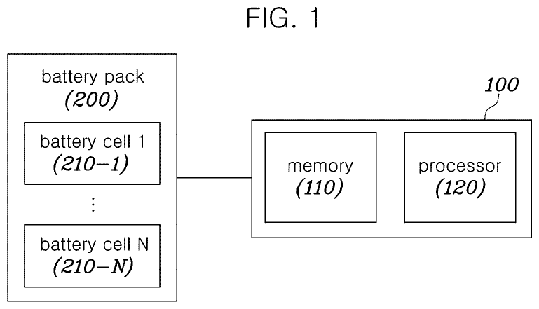

FIG. 1 is a block diagram illustrating a battery management apparatus and a battery pack of an electrified vehicle according to a disclosed embodiment.

Referring to FIG. 1, the battery management apparatus 100 of the electrified vehicle according to embodiments may perform various functions, such as monitoring the state, for example, the voltage, current, and temperature, of a battery, calculating the maximum allowable power in charging or discharging, maintaining cell balancing, performing protective measures in a case of dangerous situations including an overcurrent or a short circuit, and recording battery charging/discharging and performance data. The battery management apparatus 100 may include a memory 110 and a processor 120.

The memory 110 may store various pieces of state information including the voltage, current, temperature, and charge/discharge history of each cell 210-1 and 210-N in a battery pack 200 obtained from a plurality of sensors (not shown) for measuring the voltage, current, and temperature of the battery pack 200. In addition, the memory 110 may receive and store the resistance value of each cell determined by the processor 120 based on the voltage and current of each cell.

The processor 120 may receive data, such as the voltage, current, and temperature of each cell in the battery pack 200, from the memory 110, and may determine the resistance value of each cell through a preset calculation process. Furthermore, the processor 120 may generate various control signals for stably operating the battery pack 200.

According to an embodiment, the battery management apparatus 100 may be configured in the form of a Battery Management System (BMS).

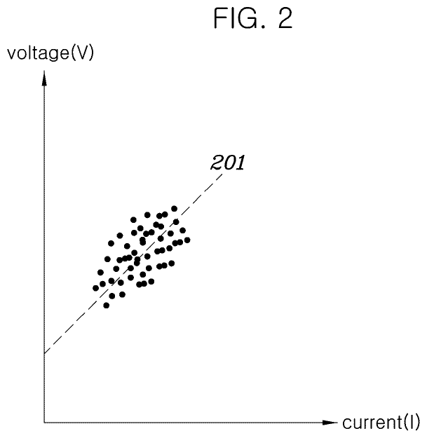

Hereinafter, abnormality types serving as criteria for determining whether each cell is abnormal, according to embodiments, are described in more detail with reference to graphs of FIGS. 2-7. In FIGS. 2-7, each graph shows only data about some cells in the battery pack 200 for convenience.

FIG. 2 is a graph illustrating an example of a process in which a processor (e.g., the processor 120) determines the resistance value of each cell, according to an embodiment.

FIG. 2 shows a graph expressing a plurality of pieces of cell voltage (V) data according to an output current (I) with respect to a specific battery cell in the battery pack 200, according to an embodiment.

In an example of a method for determining the resistance value of each cell, based on a plurality pieces of cell voltage (V) data according to an output current (I), the processor 120 may determine a linear model 201 representing the relationship between current data and voltage data of each cell stored in the memory 110 through linear regression analysis, and may determine the slope as a resistance value.

To determine the linear model representing the relationship between a current (I) and a cell voltage (V), the processor 120 may use a statistical technique, such as a least squares method or technique, that determines a linear model to minimize the square of the residual between the cell voltage and the current data and the linear model.

The processor 120 may determine the resistance value of each cell, based on the current and voltage data of each cell whenever a certain time or condition is satisfied, and the memory 110 may receive and store the resistance value of each cell.

As an example of the condition for determining the resistance value of each cell, the processor 120 may determine the resistance value only when the number of pieces of current and voltage data satisfies a threshold condition. For example, the processor 120 may determine the resistance value only when the number of pieces of current and voltage data is equal to or greater than a certain threshold number, in order to obtain a statistically significant resistance value.

In addition, to improve the reliability of the resistance value, the processor 120 may determine the resistance value only when a certain ratio or greater of cells in a charged state and cells in a discharged state are included among the battery cells. In an embodiment, the processor 120 may not determine the resistance value when all battery cells are in a charged state or in a discharged state.

Furthermore, the processor 120 may determine the resistance value according to the distribution of the voltage and current data stored in the memory 110. For example, the processor 120 may determine the resistance value only when the relationship between the current and the voltage is linearly distributed. In an example end, the processor 120 may determine whether the linear relationship is satisfied by referring to the standard deviation of data about the voltage or current.

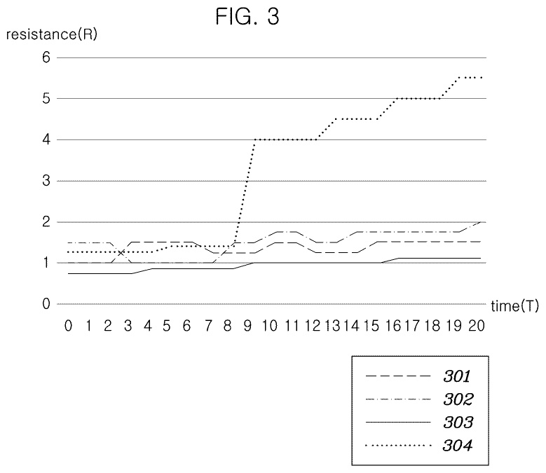

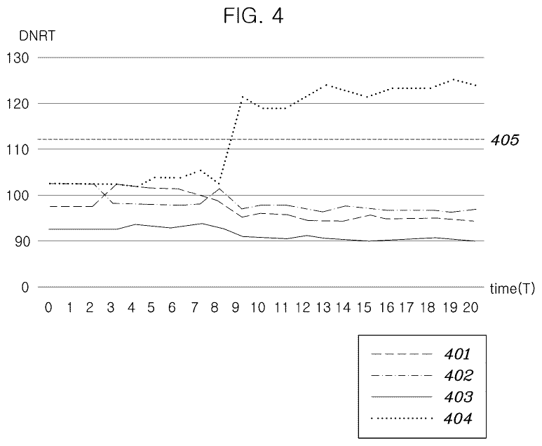

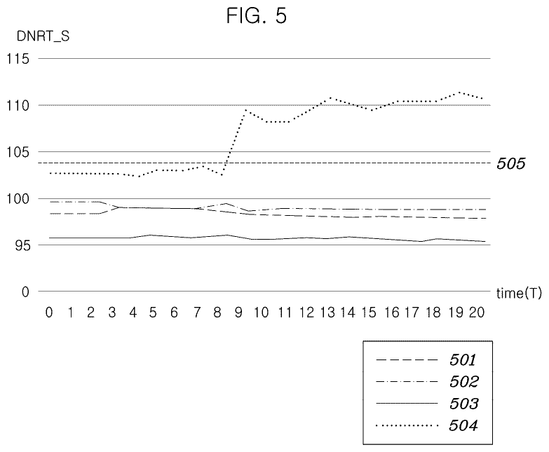

FIG. 3 is a graph showing the resistance value of each cell as a function of time stored by the memory, according to an embodiment. FIG. 4 is a graph showing data in which the resistance value of each cell is normalized, according to an embodiment. FIG. 5 is a graph showing data in which the resistance value of each cell is standardized, according to an embodiment.

FIG. 3 illustrates a graph showing data that is the resistance value (R) of each cell 301, 302, 303, and 304 stored by the memory 110 at a specific time interval (T).

The resistance values of the respective cells 301, 302, 303, and 304 may be different from each other, and may show an increasing tendency as charging and discharging are repeated.

FIG. 4 illustrates a graph showing normalized resistance value data of each cell. Data expressing a normalized resistance value as a percentage (%) may be referred to as distribution of normalized resistance for relative comparison over time (hereinafter, referred to as “DNRT”) data.

In an example of a method for normalizing the resistance value of each cell, a normalized resistance value may be determined by dividing the resistance value of each cell by the average resistance value of all cells. However, this example is only for illustration, and the present disclosure is not limited thereto. For example, in another embodiment of a normalization method, normalized resistance value data may be obtained through Min-Max normalization.

The processor 120 may normalize resistance value data determined at each specific time interval (T), in which not only new voltage and current data but also a weight for a DNRT value determined at the previous time may be further considered.

The processor 120 may diagnose whether there is an abnormality in each cell, based on DNRT data of each cell. In a method for determining whether there is an abnormality, the processor 120 may determine, as an abnormal cell, a cell having a DNRT value that satisfies a preset threshold condition. For example, the processor 120 may determine a cell having a DNRT value exceeding a preset threshold DNRT value, as an abnormal cell. Hereinafter, for convenience, a type determined as an abnormal cell due to exceeding the threshold DNRT value is referred to as “abnormality type 1.”

For example, when the preset threshold DNRT value is preset as a time-independent constant 405, the DNRT value of a specific cell 404 becomes greater than the threshold DNRT value over time, and accordingly the processor 120 may determine the specific cell 404 as an abnormal cell.

Through normalization of resistance value data, the sensitivity of an outlier may be reduced and whether there is an abnormality in each cell may be determined regardless of a vehicle type or battery type.

FIG. 5 illustrates a graph showing standardized resistance value data of each cell. Data expressing a standardized resistance value as a percentage (%) may be referred to DNRT_S data.

As with abnormality type 1, the processor 120 may determine a cell having a DNRT_S value exceeding a threshold DNRT_S value as an abnormal cell. Hereinafter, for convenience, a type determined as an abnormal cell due to exceeding the threshold DNRT_S value is referred to as “abnormality type 2.”

For example, in a case where the preset threshold DNRT_S value is a time-independent constant 505, when the standardized resistance value of a specific cell 504 becomes greater than the threshold DNRT_S value over time, the processor 120 may determine the specific cell 504 as an abnormal cell.

To determine a statistical outlier among the resistance values of the respective cells in the battery pack 200, the threshold DNRT_S value may be configured based on the standard deviation of the resistance value of each cell.

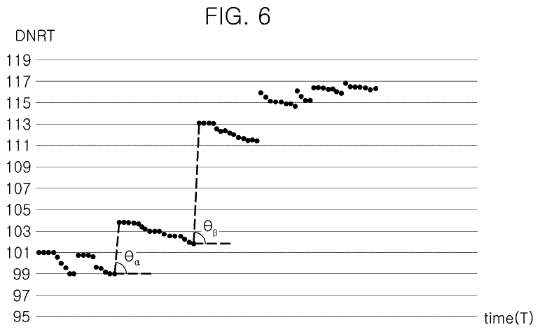

FIG. 6 is a graph showing a normalized resistance value for one cell as a function of time and a slope thereof, according to an embodiment.

In FIG. 6, it is assumed that the memory 110 stores a normalized resistance value at regular time intervals.

Referring to FIG. 6, the resistance value of a specific cell in the battery pack 200 may be measured differently over time. However, when an abnormality occurs in the specific cell, a rapid change in the resistance value may occur. Therefore, the processor 120 may diagnose a cell having the change rate of a DNRT value over time, i.e., the slope of a specific portion of DNRT data, satisfying a threshold condition (e.g., being greater than a threshold slope) as an abnormal cell. For convenience, the foregoing cell is referred to as “abnormality type 3.”

For example, when the slope ((tan(θ_{α}), tan(θ_{β})) of a portion of DNRT data of a specific cell over time is greater than the threshold slope, the processor 120 may diagnose the specific cell as an abnormal cell.

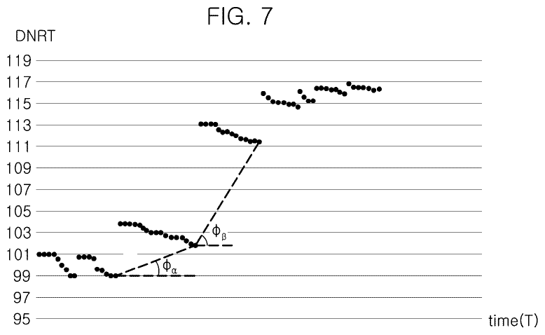

FIG. 7 is a graph showing a normalized resistance value for a specific cell over time and a slope between local minimums thereof, according to an embodiment.

Referring to FIG. 7, DNRT data of a specific cell as a function of time may include a plurality of local minimums.

The processor 120 may determine the change rate between two adjacent local minimums of the DNRT data over time, i.e., the slope between the two adjacent local minimums. In addition, the processor 120 may determine whether the specific cell is abnormal, based on the ratio between a plurality of slopes.

For example, in a case where the processor 120 obtains two slopes (tan(φ_{α}) and tan(φ_{β})) by using three adjacent minimum values, when the ratio (tan(φ_{β})/tan(φ_{α})) between the two slopes satisfies a threshold condition (e.g., is greater than a threshold ratio), the processor 120 may diagnose the cell as an abnormal cell. Hereinafter, for convenience, the foregoing cell is referred to as “abnormality type 4.”

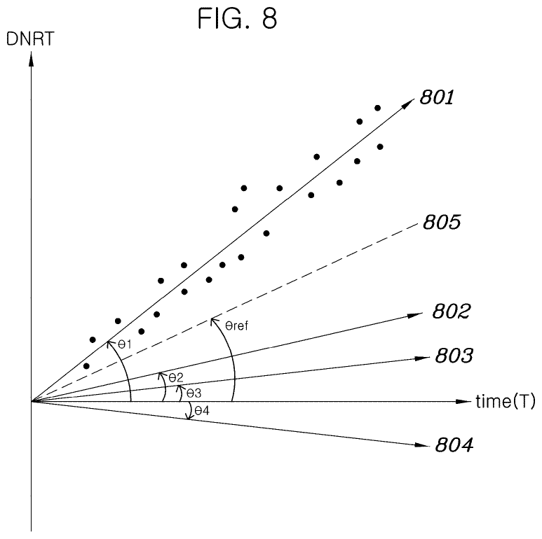

FIG. 8 is a graph comparing a change in the normalized resistance value of each cell in a battery pack as a function of time, according to an embodiment.

Referring to FIG. 8, the processor 120 may determine a trend line, which may be a linear model that represents a change in the DNRT value of each cell over time, based on DNRT data stored in the memory 110.

For example, the processor 120 may determine a trend line 801 of a DNRT value through linear regression analysis, based on DNRT data of a specific cell stored in the memory 110. Similarly, the processor 120 may analyze DNRT data (not shown) corresponding to a plurality of cells to determine trend lines 802, 803, and 804 of DNRT values respectively for each of the plurality of cells.

The processor 120 may determine a reference slope ((tan(θ_{ref})), based on the slopes ((tan(θ₁), tan(θ₂), (tan(θ₃), and tan(θ₄)) of the respective trend lines. For example, the reference slope (tan(θ_{ref})) may be determined considering the standard deviation of the slopes ((tan(θ₁), tan(θ₂), (tan(θ₃), and tan(θ₄))) of the respective trend lines. When the slope (tan(θ₁)) of the trend line 801 for the specific cell is greater than the reference slope (tan(θ_{ref})), the processor 120 may determine the specific cell as an abnormal cell. Hereinafter, for or convenience, the foregoing cell is referred to as “abnormality type 5.”

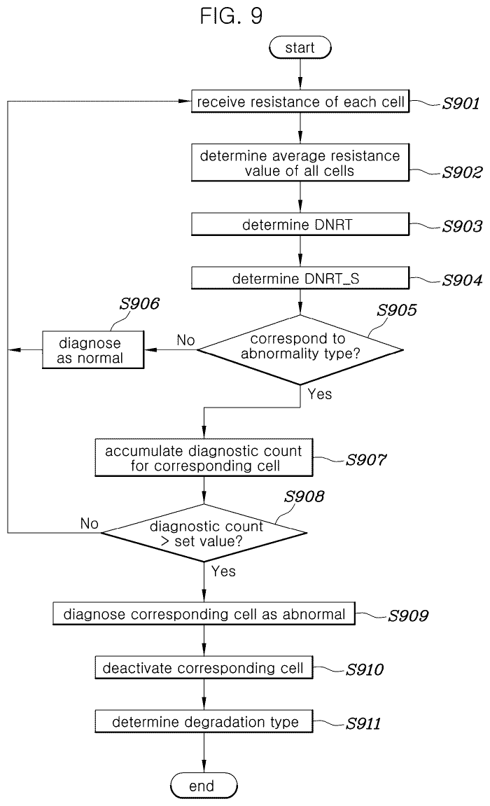

FIG. 9 is a flowchart illustrating an example of a process in which a processor determines whether a cell is abnormal and an abnormality type, according to an embodiment.

Referring to FIG. 9, in an operation S901, the processor 120 may receive the resistance value of each cell stored in the memory 110. In an operation S902, the processor 120 may determine the average resistance value of all cells.

In an operation S903, the processor 120 may determine DNRT data obtained by normalizing the resistance of each cell. In an operation S904, the processor 120 may determine DNRT_S data obtained by standardizing the resistance of each cell, based on the determined average resistance value of all cells.

In an operation S905, the processor 120 may determine whether each cell corresponds to one of abnormality types 1 to 5, based on the determined DNRT data and DNRT_S data of each cell.

When a specific cell does not correspond to any of abnormality types 1 to 5, the processor 120 may, in an operation S906, diagnose the specific cell as a normal cell.

On the other hand, when the specific cell corresponds to one or more of the abnormality types, the processor 120 may, in an operation S907, accumulate a diagnostic count for a corresponding abnormality type.

In an operation S908, the processor 120 may determine whether a diagnostic count for a specific abnormality type is greater than a preset value. When the diagnostic count for a specific abnormality type is greater than the preset value, the processor 120 may diagnose a corresponding cell as an abnormal cell in an operation S909, and may deactivate the cell in an operation S910.

In an operation S911, the processor 120 may determine a degradation type according to the abnormality type of the abnormal cell. The processor 120 may determine the degradation type by referring to a table in which the degradation type is distinguished according to the number of abnormality types to which the abnormal cell corresponds and the number of diagnostic counts for each abnormality type, and may generate a notification signal for transmitting information about the abnormal cell and information about the degradation type to an external controller.

For example, the processor 120 may distinguish whether Loss of Lithium Inventory (LLI) has occurred in the abnormal cell or whether a lithium ion storage space shortage due to Loss of Active Material in an electrode (LAM) has occurred by referring to the table in which the degradation type is distinguished.

Although the present disclosure has been described and illustrated in conjunction with example embodiments thereof, it should be apparent to those having ordinary skill in the art that various improvements and modifications may be made to the present disclosure without departing from the technical idea of the present disclosure defined by the appended claims.

What is claimed is:

1. A battery management apparatus comprising:
a memory configured to store a resistance value of each battery cell among a plurality of battery cells of a battery; and
a processor configured to
determine i) whether there is an abnormality in each battery cell among the plurality of battery cells and ii) an abnormality type, based on the resistance value of each battery cell, and
control each battery cell, among the plurality of battery cells, according to whether there is the abnormality in the battery cell and the abnormality type.

2. The battery management apparatus of claim 1, wherein the processor is configured to determine whether there is the abnormality in each battery cell based on resistance value data normalized by dividing the resistance value of each battery cell by an average resistance value of all battery cells among the plurality of battery cells.

3. The battery management apparatus of claim 1, wherein the processor is configured to determine whether there is the abnormality in each battery cell based on standardized resistance value data obtained by standardizing the resistance value of the battery cell.

4. The battery management apparatus of claim 2, wherein the processor is configured to determine, as an abnormal cell, a battery cell, among the plurality of battery cells, having a normalized resistance value that satisfies a preset first threshold condition.

5. The battery management apparatus of claim 2, wherein the processor is configured to determine whether there is the abnormality in a battery cell, among the plurality of battery cells, based on a change rate of a normalized resistance value of the battery cell over time.

6. The battery management apparatus of claim 2, wherein the processor is configured to determine whether there is the abnormality in a battery cell, among the plurality of battery cells, based on a change rate of a plurality of local minimums in a graph representing a normalized resistance value of the battery cell over time.

7. The battery management apparatus of claim 2, wherein the processor is configured to determine whether there is the abnormality by comparing slopes of linear models, each linear model representing a change in a normalized resistance value a battery cell, among the plurality of battery cells, over time.

8. The battery management apparatus of claim 3, wherein the processor is configured to determine, as an abnormal cell, a battery cell, among the plurality of battery cells, having a standardized resistance value that satisfies a preset second threshold condition,.

9. The battery management apparatus of claim 1, wherein the processor is configured to, based on determining that there is an abnormal cell, among the plurality of battery cells, deactivate the abnormal cell.

10. The battery management apparatus of claim 9, wherein the processor is further configured to determine a degradation type of the abnormal cell according to the abnormality type.

11. The battery management apparatus of claim 1, wherein the processor is configured to determine a battery cell, among the plurality of battery cells, as an abnormal cell and deactivate the battery cell, based on a condition that a preset number or more of a same abnormality type is accumulated in any one of the battery cells.

12. The battery management apparatus of claim 1, wherein the processor is further configured to determine the resistance value of each battery cell by performing regression analysis according to a preset condition, based on current and voltage data of the battery cell.

13. The battery management apparatus of claim 12, wherein the processor is further configured to:
determine, for each battery cell among the plurality of battery cells, a linear model representing a relationship between the current and voltage data of the battery cell by using a least squares technique; and
determine, for each battery cell among the plurality of battery cells, the resistance value of the battery cell based on a slope of the linear model.

14. The battery management apparatus of claim 12, wherein the preset condition is configured based on a charging and discharging ratio in each battery cell.

15. The battery management apparatus of claim 12, wherein the preset condition is configured based on a distribution of the current and voltage data of each battery cell.

16. A battery management method comprising:
storing a resistance value of each battery cell among a plurality of battery cells of a battery;
determining whether there is an abnormality in each battery cell, among the plurality of battery cells, based on the resistance value of the battery cell; and
selectively deactivating each battery cell according to whether there is the abnormality in the battery cell.

17. The battery management method of claim 16, wherein determining whether there is the abnormality in each battery cell includes determining whether there is the abnormality in each battery cell based on resistance value data normalized by dividing the resistance value of each battery cell by an average resistance value of all battery cells and standardized resistance value data obtained by standardizing the resistance value of each battery cell.

18. The battery management method of claim 17, wherein determining whether there is the abnormality in each battery cell, among the plurality of battery cells, includes determining, as an abnormal cell, a battery cell having a normalized resistance value that satisfies a preset first threshold condition or a battery cell having a standardized resistance value that satisfies a preset second threshold condition.

19. The battery management method of claim 17, wherein determining whether there is the abnormality in a battery cell, among the plurality of battery cells, includes determining whether there is the abnormality based on a change rate of a normalized resistance value of the battery cell over time.

20. The battery management method of claim 17, wherein determining whether there is the abnormality in a battery cell, among the plurality of battery cells, includes determining whether there is the abnormality by comparing slopes of linear models, each linear model representing a change in a normalized resistance value of a battery cell, among the plurality of battery cells, over time.
